(19) United States
(12) Patent Application Publication
(10) Pub. No.: US 2025/0331119 A1
(43) Pub. Date: Oct. 23, 2025

(54) PHOTOVOLTAIC INTEGRATED CABINET AND DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/939,520

(22) Filed: Nov. 7, 2024

(30) Foreign Application Priority Data
Nov. 17, 2023 (CN) 202311542413.8

(51) Int. Cl. H05K 7/14; H05K 7/18; H05K 7/20

(52) U.S. Cl. CPC H05K 7/1488; H05K 7/18; H05K 7/20718

(57) ABSTRACT

The present disclosure discloses a photovoltaic integrated cabinet and a data center. The photovoltaic integrated cabinet includes a cabinet body, and a hand-controlled drainage structure is installed at a rear of the cabinet body. A top end of the hand-controlled drainage structure is communicated with a rainwater collection part, where each of two sides of the rainwater collection part is provided with an overflow pipe.

### CROSS-REFERENCE TO RELATED APPLICATION

This application claims priority to Chinese Patent Application No. 202311542413.8, titled “PHOTOVOLTAIC INTEGRATED CABINET AND DATA CENTER” and filed to the China National Intellectual Property Administration on Nov. 17, 2023, the entire contents of which are incorporated herein by reference.

### TECHNICAL FIELD

The present disclosure relates to the field of data center, and more particularly, to a photovoltaic integrated cabinet and a data center.

### BACKGROUND

As main outlets of photovoltaic power plants, photovoltaic integrated cabinets exist in photovoltaic systems. The photovoltaic integrated cabinets are generally used to protect internal servers and electrical components, and to dissipate heat from the servers and the electrical components through heat emission holes and cooling fans.

According to specific application needs, some photovoltaic integrated cabinets need to be installed in outdoor environments. In the changeable outdoor environment, when heavy rain strikes, rainwater can easily enter cabinet bodies through the heat emission holes provided on surfaces of the cabinet bodies, which may cause damage to the internal servers or electrical components. However, if no heat emission holes are provided for heat dissipation, heat inside the cabinet bodies cannot dissipate quickly in hot weather, which may adversely affect normal operation of the internal components. Therefore, researching a new photovoltaic integrated cabinet is of great significance to solve the above problems.

### SUMMARY

An objective of the present disclosure is to provide a photovoltaic integrated cabinet and a data center, to facilitate dissipation of heat inside a cabinet body in hot weather. Furthermore, heat emission holes may be automatically closed in heavy rain, and rapid heat dissipation of the photovoltaic integrated cabinet is achieved through rainwater flowing through heat sink fins.

To achieve the above objective, the present disclosure provides a photovoltaic integrated cabinet, which at least includes a cabinet body. A hand-controlled drainage structure is installed at a rear of the cabinet body, where a top end of the hand-controlled drainage structure is communicated with a rainwater collection part, and each of two sides of the rainwater collection part is provided with an overflow pipe, which is internally provided with a valve structure. A first spring is fixedly connected between the rainwater collection part and the cabinet body. Four slide plates are fixedly connected below the rainwater collection part, the four slide plates penetrate through the cabinet body, two of the four slide plates are fixedly connected to a same sealing plate, and two sealing plates are positioned on two side walls of the cabinet body. A plurality of first radiating fins and a plurality of second radiating fins are embedded on each of two sides of the cabinet body, a connecting rod is fixedly connected above two uppermost first radiating fins, and the connecting rod corresponds to the valve structure.

As further improvement of the above technical solutions, a plurality of filter layers are embedded on each of two sides of the cabinet body, the sealing plate is provided with a plurality of openings, and the plurality of openings correspond to the plurality of filter layers.

As further improvement of the above technical solutions, a cabinet door is provided in a front of the cabinet body, a base is fixedly connected to a bottom of the cabinet body, and instrument racks are provided on two sides of the two side walls of the cabinet body.

As further improvement of the above technical solutions, the rainwater collection part includes a collection hopper, and the collection hopper is provided with a filter net. A bottom of the collection hopper is fixedly connected to a collection box, a bottom of the collection box is fixedly connected to two first springs, and two overflow pipes are arranged on two sides of the collection box, respectively, where an opening on a top of the overflow pipe is positioned above the filter layer.

As further improvement of the above technical solutions, the first radiating fin and every two second radiating fin are arranged in a staggered pattern, and the second radiating fins in a same row are aslant arranged, and two sides of the first radiating fin are aslant arranged.

As further improvement of the above technical solutions, the hand-controlled drainage structure includes a water outlet pipe communicated with the collection box, where a bottom of the water outlet pipe is communicated with a water faucet, and the water outlet pipe is externally fixed to two fixed parts, which are installed at a rear of the cabinet body.

As further improvement of the above technical solutions, a cooling fan is installed on a top of the cabinet body, where a switch is installed on a top of the cooling fan, and a pressure lever is arranged in a middle below the collection box.

As further improvement of the above technical solutions, the valve structure includes a sealing cone, which is fixedly connected into the overflow pipe. A sealing ball is embedded in a middle of the sealing cone, where a top of the sealing ball is fixedly connected to a connecting piece, and a second spring is fixedly connected between the connecting piece and the sealing cone.

To achieve the above objective, the present disclosure provides a data center, which at least includes the photovoltaic integrated cabinet as mentioned above, where the cabinet body is configured to accommodate a server.

As can be seen from the technical solutions provided by the present disclosure, rainwater is collected by means of the rainwater collection part to make rational use of the rainwater, thereby saving water resources, and making it easier for maintenance personnel to wash hands after repair and maintenance of the cabinet body. Furthermore, in heavy rain, the rainwater collection part overcomes the first spring and moves down, such that the slide plate drives the sealing plate to move down. An opening of the sealing plate is staggered from a filter layer, thus playing a role of sealing the cabinet body. Therefore, it is avoided a problem of causing short circuit or electric leakage to internal devices because the rainwater enters the cabinet body in the heavy rain. Moreover, the connecting rod jacks up the sealing ball, such that the rainwater is discharged downward through the overflow pipe, then the rainwater lowers temperature when it passes through the first radiating fin and the second radiating fin, thereby ensuring the first radiating fin and the second radiating fin to be in a good heat conduction state.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of an opened photovoltaic integrated cabinet according to an embodiment provided by the present disclosure;

FIG. 2 is a schematic rear view of the photovoltaic integrated cabinet according to an embodiment provided by the present disclosure;

FIG. 3 is a schematic installation diagram of a cooling fan in the photovoltaic integrated cabinet according to an embodiment provided by the present disclosure;

FIG. 4 is a schematic three-dimensional diagram of a sealing plate of the photovoltaic integrated cabinet according to an embodiment provided by the present disclosure;

FIG. 5 is a schematic cross-sectional view of the photovoltaic integrated cabinet according to an embodiment provided by the present disclosure; and

FIG. 6 is an enlarged view of Region A in FIG. 5.

Reference numerals in the accompanying drawings: cabinet body 1; cabinet door 2; hand-controlled drainage structure 3; water faucet 31; water outlet pipe 32; fixed part 33; base 4; first radiating fin 5; rainwater collection part 6; collection hopper 61; filter net 62; collection box 63; second radiating fin 7; first spring 8; switch 9; cooling fan 10; connecting rod 11; overflow pipe 12; valve structure 13; sealing ball 131; second spring 132; connecting piece 133; sealing cone 134; sealing plate 14; slide plate 15; filter layer 16; and instrument rack 17.

### DETAILED DESCRIPTION

To make the objectives, technical solutions and advantages of the present disclosure clearer, the embodiments of the present disclosure will be further described in detail below with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or internal communication between two apparatuses, elements, or constituent parts. The specific significations of the above terms in the present disclosure may be understood in the light of specific conditions by persons of ordinary skill in the art.

The technical solutions in the embodiments of the present disclosure will be described clearly and completely below in conjunction with the accompanying drawings. Apparently, the embodiments described in the present disclosure are some but not all of the embodiments of the present disclosure. All other embodiments obtained by those skilled in the art based on the embodiments of the present disclosure without creative efforts shall fall within the protection scope of the present disclosure.

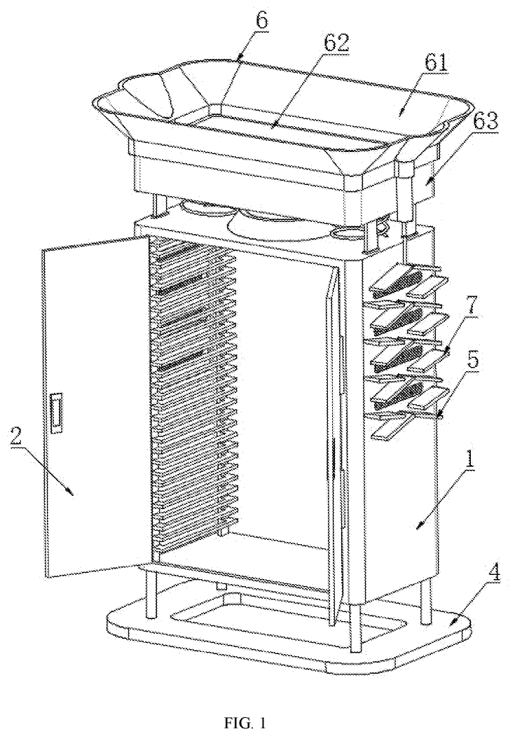

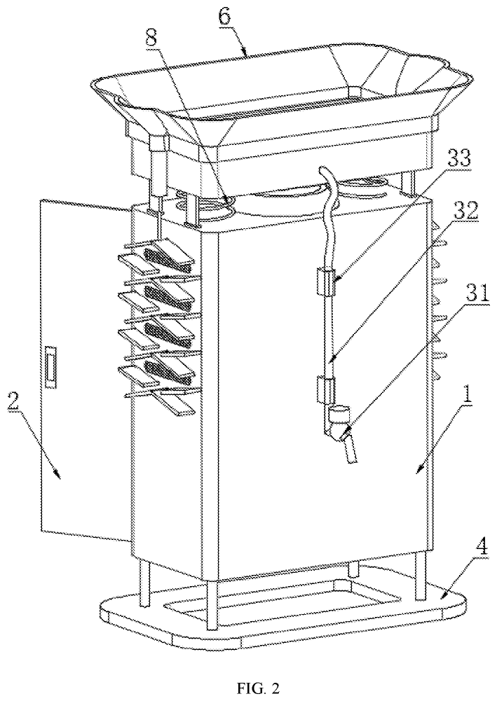

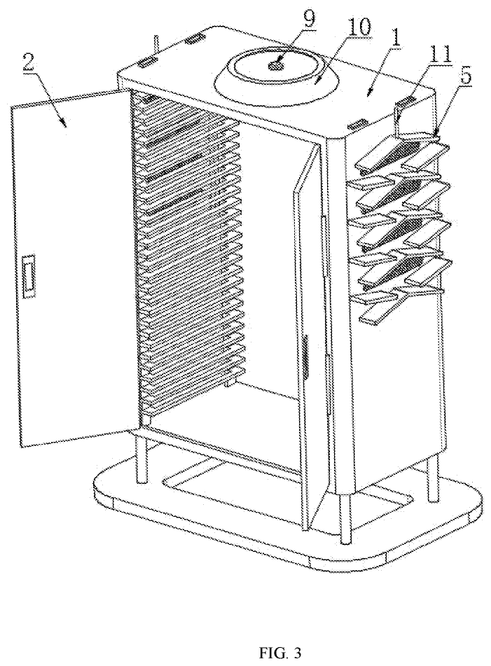

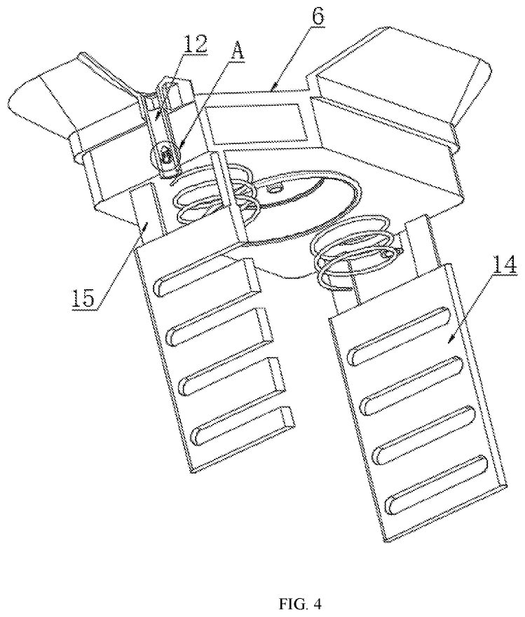

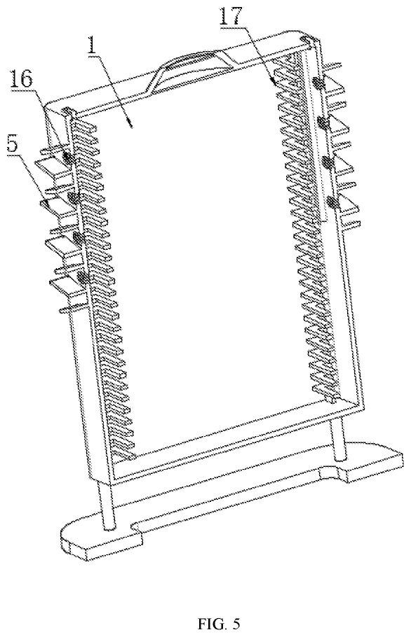

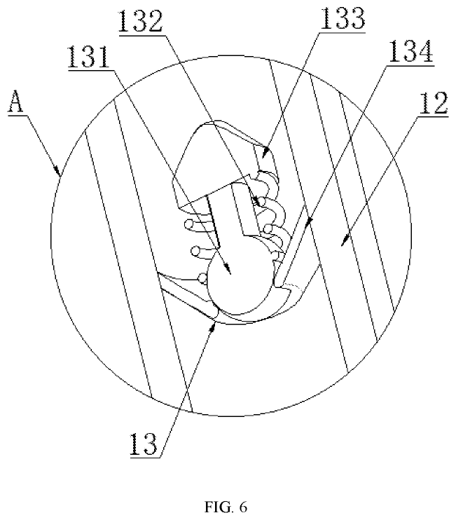

The present disclosure provides a photovoltaic integrated cabinet. As shown in FIGS. 1 to 6, the photovoltaic integrated cabinet at least includes a cabinet body 1. A photovoltaic panel component may be provided on an outer surface of cabinet body, and an energy storage unit is arranged inside cabinet body 1. The photovoltaic panel component supplies power to the energy storage unit. A cooling fan 10 may be installed on a top of the cabinet body 1. The energy storage unit supplies power to the cooling fan 10, such that the cooling fan 10 can accelerate flow speed of air inside the cabinet body 1, which can accelerate heat transfer speed inside the cabinet body 1, thereby improving heat dissipation effects.

In one embodiment, a switch 9 is installed on a top of the cooling fan 10, and a pressure lever is arranged in a middle below the collection box 63. When the collection box 63 moves downwards, the pressure lever presses the switch 9 downwards, which can control the cooling fan 10 to stop operating. A plurality of filter layers 16 are embedded are embedded on two sides of the cabinet body 1, and the plurality of filter layers 16 can ensure air ventilation of the cabinet body 1 and filter impurities. The sealing plate 14 is provided with a plurality of openings, which correspond to the plurality of filter layers 16. A cabinet door 2 is provided in a front of the cabinet body 1, and a base 4 is fixedly connected to a bottom of the cabinet body 1. Instrument racks 17 are provided on two sides of the two side walls of the cabinet body 1. The instrument racks 17 can mount and fix shelves, making it easy to fix electrical components.

In this embodiment, a hand-controlled drainage structure 3 is installed at a rear of cabinet body 1. It should be pointed out that the rear as defined in the present disclosure refers to a direction opposite to a normal service side. That is, a side where the cabinet door 2 of cabinet body 1 is positioned is the front, and the other side is the rear.

In one embodiment, the hand-controlled drainage structure 3 may include a water outlet pipe 32 communicated with the collection box 63, where a bottom of the water outlet pipe 32 is communicated with a water faucet 31, and the water outlet pipe 32 is externally fixed to two fixed parts 33, which are installed at a rear of the cabinet body 1. The two fixed parts 33 serve to reinforce the water outlet pipe 32. Meanwhile, the water faucet 31 is operated to drain water, such that the water outlet pipe 32 drains the rainwater, which can be used for maintenance personnel to wash hands. A top end of the hand-controlled drainage structure 3 is communicated with a rainwater collection part 6, and the rainwater collection part 6 includes a collection hopper 61. The collection hopper 61 is provided with a filter net 62, which can filter impurities in the rainwater. A bottom of the collection hopper 61 is fixedly connected to the collection box 63, and a bottom of the collection box 63 is fixedly connected to two first springs 8, where elastic force of the first spring 8 can restore the collection box 63 to its original state. Two overflow pipes 12 are arranged on two sides of the collection box 63, respectively. An opening on a top of the overflow pipe 12 is positioned above the filter layer 16, and each of the two sides of the rainwater collection part 6 is provided with the overflow pipe 12.

Further, the overflow pipe 12 is internally provided with a valve structure 13, which includes a sealing cone 134 fixedly connected into the overflow pipe 12. A sealing ball 131 is embedded in a middle of the sealing cone 134, where a top of the sealing ball 131 is fixedly connected to a connecting piece 133, and a second spring 132 is fixedly connected between the connecting piece 133 and the sealing cone 134. Elastic force of the second spring 132 can drive the sealing ball 131 to move downward to restore to its original state, such that sealing is formed between the sealing ball 131 and the sealing cone 134. Furthermore, when the collection box 63 moves downward, the connecting rod 11 jacks up the sealing ball 131, such that the overflow pipe 12 can discharge excess rainwater successfully. In addition, the first spring 8 is fixedly connected between the rainwater collection part 6 and the cabinet body 1.

In one embodiment, four slide plates 15 are fixedly connected below the rainwater collection part 6, and the four slide plates 15 penetrate through the cabinet body 1, where two of the four slide plates 15 are fixedly connected to the same sealing plate 14, and two sealing plates 14 are positioned on two side walls of the cabinet body 1. The collection box 63 moves down to drive the sealing plate 14 to move downwards, such that the opening of the sealing plate 14 is staggered from the filter layer 16, and thus the cabinet body 1 is kept to be sealed to prevent the rainwater from entering the cabinet body 1. A plurality of first radiating fins 5 and a plurality of second radiating fins 7 are embedded on each of two sides of the cabinet body 1. The first radiating fin 5 and every two second radiating fin 7 are arranged in a staggered pattern, the second radiating fins 7 in a same row are aslant arranged, and two sides of the first radiating fin 5 are aslant arranged. The first radiating fins 5 and the second radiating fins 7 can guide internal heat of the cabinet body 1 to be discharged, which facilitates heat dissipation of electric appliances inside the cabinet body 1. Moreover, the staggered and aslant arrangement between the first radiating fins 5 and the second radiating fins 7 can guide the rainwater to flow step by step, making it easier for the first radiating fins 5 and the second radiating fins 7 to cool down. The connecting rod 11 is fixedly connected above two uppermost first radiating fins 5, and the connecting rod 11 corresponds to the valve structure 13.

The present disclosure also provides a data center, which at least includes the above-mentioned photovoltaic integrated cabinet, where the cabinet body is configured to accommodate a server.

It should be pointed out that reference may be made to the contents in the above embodiments for the specific structure of the photovoltaic integrated cabinet, which is not to be described in detail here.

It is worth mentioning that the above-mentioned photovoltaic integrated cabinet is not only used for installing the server, but also may be used as a carrier for other equipment, and is not limited thereto in the present disclosure.

In Application Scenario I, when it rains, the rainwater is filtered by the collection hopper 61 and the filter net 62 and then flows into the collection box 63. After the maintenance personnel repair or maintain the cabinet body 1, the water faucet 31 can be operated to discharge the rainwater, such that the rainwater is discharged through the water outlet pipe 32, so the maintenance personnel can wash their hands. In the event of heavy rain, the rainwater accumulates and overflows from the filter net 62. At this moment, the collection box 63 and the rainwater push down the first spring 8 under gravity, so the collection box 63 drives the slide plate 15 and the sealing plate 14 to move downwards, such that the opening of the sealing plate 14 is staggered from the filter layer 16. In this case the cabinet body 1 is kept to be sealed to prevent the rainwater from entering the cabinet body 1. Meanwhile, the collection box 63 drives the pressure lever to press down the switch 9, such that the cooling fan 10 may be controlled to stop running. When the rainfall decreases or stops, because the overflow pipe 12 is downward, the connecting rod 11 extrudes the sealing ball 131 upward, such that the sealing ball 131 is separated from the sealing cone 134. In this case, the excess rainwater can be discharged through the overflow pipe 12. After the rainwater is discharged, the first spring 8 drives the collection box 63 to move upward and restore to its original state, so the opening on the sealing plate 14 corresponds to the filter layer 16, such that ventilation and heat dissipation can be carried out for the cabinet body 1.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A photovoltaic integrated cabinet at least comprising a cabinet body (1), wherein a hand-controlled drainage structure (3) is installed at a rear of the cabinet body (1);
a top end of the hand-controlled drainage structure (3) is communicated with a rainwater collection part (6), each of two sides of the rainwater collection part (6) is provided with an overflow pipe (12), the overflow pipe (12) is internally provided with a valve structure (13), and a first spring (8) is fixedly connected between the rainwater collection part (6) and the cabinet body (1); and
four slide plates (15) are fixedly connected below the rainwater collection part (6), the four slide plates (15) penetrate through the cabinet body (1), two of the four slide plates (15) are fixedly connected to a same sealing plate (14), two sealing plates (14) are positioned on two side walls of the cabinet body (1), a plurality of first radiating fins (5) and a plurality of second radiating fins (7) are embedded on each of two sides of the cabinet body (1), a connecting rod (11) is fixedly connected above two uppermost first radiating fins (5), and the connecting rod (11) corresponds to the valve structure (13).

2. The photovoltaic integrated cabinet according to claim 1, wherein a plurality of filter layers (16) are embedded on two sides of the cabinet body (1), and the sealing plate (14) is provided with a plurality of openings, and the plurality of openings correspond to the plurality of filter layers (16).

3. The photovoltaic integrated cabinet according to claim 2, wherein a cabinet door (2) is provided in a front of the cabinet body (1); and
a base (4) is fixedly connected to a bottom of the cabinet body (1), and instrument racks (17) are provided on two sides of the two side walls of the cabinet body (1).

4. The photovoltaic integrated cabinet according to claim 3, wherein the rainwater collection part (6) comprises a collection hopper (61); and
the collection hopper (61) is provided with a filter net (62), a bottom of the collection hopper (61) is fixedly connected to a collection box (63), a bottom of the collection box (63) is fixedly connected to two first springs (8), and two overflow pipes (12) are arranged on two sides of the collection box (63), respectively, and an opening on a top of the overflow pipe (12) is positioned above the filter layer (16).

5. The photovoltaic integrated cabinet according to claim 4, wherein the first radiating fin (5) and every two second radiating fin (7) are arranged in a staggered pattern, and the second radiating fins (7) in a same row are aslant arranged, and two sides of the first radiating fin (5) are aslant arranged.

6. The photovoltaic integrated cabinet according to claim 4, wherein the hand-controlled drainage structure (3) comprises a water outlet pipe (32); and
the water outlet pipe (32) is communicated with the collection box (63), a bottom of the water outlet pipe (32) is communicated with a water faucet (31), the water outlet pipe (32) is externally fixed to two fixed parts (33), and the two fixed parts (33) are installed at a rear of the cabinet body (1).

7. The photovoltaic integrated cabinet according to claim 4, wherein a cooling fan (10) is installed on a top of the cabinet body (1); and
a switch (9) is installed on a top of the cooling fan (10), and a pressure lever is arranged in a middle below the collection box (63).

8. The photovoltaic integrated cabinet according to claim 1, wherein the valve structure (13) comprises a sealing cone (134); and
the sealing cone (134) is fixedly connected into the overflow pipe (12), a sealing ball (131) is embedded in a middle of the sealing cone (134), a top of the sealing ball (131) is fixedly connected to a connecting piece (133), and a second spring (132) is fixedly connected between the connecting piece (133) and the sealing cone (134).

9. A data center comprising the photovoltaic integrated cabinet according to claim 8, wherein the cabinet body (1) is configured to accommodate a server.
